(19) United States
(12) Patent Application Publication
(10) Pub. No.: US 2026/0058607 A1
(43) Pub. Date: Feb. 26, 2026

(54) DIGITAL VOLTAGE RECONSTRUCTION IN A POWER MANAGEMENT CIRCUIT

(71) Applicant: Qorvo US, Inc., Greensboro, NC (US)

(72) Inventor: Nadim Khlat, Ceret (FR)

(21) Appl. No.: 19/250,341

(22) Filed: Jun. 26, 2025

Related U.S. Application Data
(60) Provisional application No. 63/684,967, filed on Aug. 20, 2024.
(60) Provisional application No. 63/700,839, filed on Sep. 30, 2024.

(51) Int. Cl. H03F 1/02; H03F 3/24; H04B 1/38

(52) U.S. Cl. CPC H03F 1/0233; H03F 3/245; H04B 1/38; H03F 2200/105; H03F 2200/451

(57) ABSTRACT

Digital voltage reconstruction in a power management circuit is provided. The power management circuit, which includes a transceiver circuit, a power management integrated circuit (PMIC), and a power amplifier circuit, is configured to generate a modulated voltage (e.g., envelope tracking voltage) to amplify a radio frequency (RF) signal for transmission. In embodiments disclosed herein, the transceiver circuit is configured to digitally estimate a time-variant load current in the power amplifier circuit to thereby determine a voltage reconstruction term that can offset a ripple created in the modulated voltage by an interaction of the time-variant load current and an inherent impedance of the power amplifier circuit. By digitally generating the voltage reconstruction term in the transceiver circuit, it is possible to effectively cancel the ripple to ensure that the power amplifier circuit can operate with an improved linearity and the PMIC can be implemented on a reduced footprint.

### RELATED APPLICATIONS

This application claims the benefit of U.S. provisional patent application Ser. No. 63/684,967, filed on Aug. 20, 2024, and U.S. provisional patent application Ser. No. 63/700,839, filed on Sep. 30, 2024, the disclosures of which are hereby incorporated herein by reference in their entireties.

### FIELD OF THE DISCLOSURE

The present disclosure is related to digitally reconstructing a modulated voltage, such as an envelope tracking (ET) voltage, in a power management circuit.

### BACKGROUND

Mobile communication devices have become increasingly common in current society for providing wireless communication services. The prevalence of these mobile communication devices is driven in part by the many functions that are now enabled on such devices. Increased processing capabilities in such devices means that mobile communication devices have evolved from being pure communication tools into sophisticated mobile multimedia centers that enable enhanced user experiences.

The redefined user experience requires higher data rates offered by advanced wireless communication technologies such as fifth-generation new-radio (5G-NR). To achieve higher data rates, a mobile communication device is required to amplify a transmission signal to a desired power level to help overcome potential propagation losses and/or interferences. As such, the mobile communication device typically includes a transceiver circuit, a power amplifier circuit, and a power management circuit. Specifically, the transceiver circuit generates and modulates the transmission signal to an intended transmission frequency, the power amplifier circuit amplifies the transmission signal to the desired power level, and the power management circuit supplies a modulated voltage to the power amplifier circuit for amplifying the transmission signal to the desired power level. Understandably, to achieve the best possible efficiency, linearity, and performance, the power management circuit must generate and adapt the modulated voltage in accordance with a time-variant power envelope of the transmission signal across a wide modulation bandwidth of the transmission signal.

### SUMMARY

Embodiments of the disclosure relate to digital voltage reconstruction in a power management circuit. The power management circuit, which includes a transceiver circuit, a power management integrated circuit (PMIC), and a power amplifier circuit, is configured to generate a modulated voltage (e.g., envelope tracking voltage) to amplify a radio frequency (RF) signal for transmission. In embodiments disclosed herein, the transceiver circuit is configured to digitally estimate a time-variant load current in the power amplifier circuit to thereby determine a voltage reconstruction term that can offset a ripple created in the modulated voltage by an interaction of the time-variant load current and an inherent impedance of the power amplifier circuit. By digitally generating the voltage reconstruction term in the transceiver circuit, it is possible to effectively cancel the ripple to ensure that the power amplifier circuit can operate with an improved linearity and the PMIC can be implemented on a reduced footprint.

In one aspect, a power management circuit is provided. The power management circuit includes a PMIC. The PMIC is configured to generate a modulated voltage at a voltage output based on a modulated target voltage. The power management circuit also includes a power amplifier circuit. The power amplifier circuit is configured to amplify an RF signal from a time-variant input power to a time-variant output power based on a modulated voltage and modulate a load line impedance at the voltage output based on the time-variant output power. The power management circuit also includes a transceiver circuit. The transceiver circuit includes a target voltage circuit. The target voltage circuit is configured to generate the modulated target voltage and provide the modulated target voltage to the PMIC. The target voltage circuit is also configured to digitally estimate a time-variant load current in the power amplifier circuit and determine a voltage reconstruction term based on the estimated time-variant load current. The target voltage circuit is also configured to add the voltage reconstruction term to the modulated target voltage to thereby offset a ripple created in the modulated voltage when the time-variant load current interacts with the load line impedance.

In another aspect, a wireless device is provided. The wireless device includes a power management circuit. The power management circuit includes a PMIC. The PMIC is configured to generate a modulated voltage at a voltage output based on a modulated target voltage. The power management circuit also includes a power amplifier circuit. The power amplifier circuit is configured to amplify an RF signal from a time-variant input power to a time-variant output power based on a modulated voltage and modulate a load line impedance at the voltage output based on the time-variant output power. The power management circuit also includes a transceiver circuit. The transceiver circuit includes a target voltage circuit. The target voltage circuit is configured to generate the modulated target voltage and provide the modulated target voltage to the PMIC. The target voltage circuit is also configured to digitally estimate a time-variant load current in the power amplifier circuit and determine a voltage reconstruction term based on the estimated time-variant load current. The target voltage circuit is also configured to add the voltage reconstruction term to the modulated target voltage to thereby offset a ripple created in the modulated voltage when the time-variant load current interacts with the load line impedance.

In another aspect, a method for supporting digital voltage reconstruction in a power management circuit is provided. The method includes generating a modulated voltage based on a modulated target voltage. The method includes amplifying an RF signal from a time-variant input power to a time-variant output power based on the modulated voltage and modulating a load line impedance based on the time-variant output power. The method also includes generating the modulated target voltage. The method also includes digitally estimating a time-variant load current in the power amplifier circuit and determining a voltage reconstruction term based on the estimated time-variant load current. The method also includes adding the voltage reconstruction term to the modulated target voltage to thereby offset a ripple created in the modulated voltage when the time-variant load current interacts with the load line impedance.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure and, together with the description, serve to explain the principles of the disclosure.

FIG. 1 is a schematic diagram of an exemplary power management circuit wherein a power management integrated circuit (PMIC) can generate a modulated voltage in accordance with a modulated target voltage for amplifying a radio frequency (RF) signal from a time-variant input power to a time-variant output power;

FIG. 2 is a diagram providing an exemplary illustration as to how the power management circuit of FIG. 1 is operable to generate the modulated voltage in accordance with the time-variant input power and/or the time-variant output power of the RF signal;

FIG. 3 is a schematic diagram of an exemplary power management circuit configured according to embodiments of the present disclosure to support digital voltage reconstruction to thereby remove an unwanted voltage ripple from a modulated voltage at a power amplifier circuit;

FIGS. 4A and 4B are schematic diagrams illustrating various configurations of the power management circuit of FIG. 3;

FIG. 5 is a schematic diagram of an exemplary communication device wherein the power management circuit of FIGS. 3, 4A, and 4B can be provided; and

FIG. 6 is a flowchart of an exemplary process whereby the power management circuit of FIG. 3 can be configured to support digital voltage reconstruction.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to digital voltage reconstruction in a power management circuit. The power management circuit, which includes a transceiver circuit, a power management integrated circuit (PMIC), and a power amplifier circuit, is configured to generate a modulated voltage (e.g., envelope tracking voltage) to amplify a radio frequency (RF) signal for transmission. In embodiments disclosed herein, the transceiver circuit is configured to digitally estimate a time-variant load current in the power amplifier circuit to thereby determine a voltage reconstruction term that can offset a ripple created in the modulated voltage by an interaction of the time-variant load current and an inherent impedance of the power amplifier circuit. By digitally generating the voltage reconstruction term in the transceiver circuit, it is possible to effectively cancel the ripple to ensure that the power amplifier circuit can operate with an improved linearity and the PMIC can be implemented on a reduced footprint.

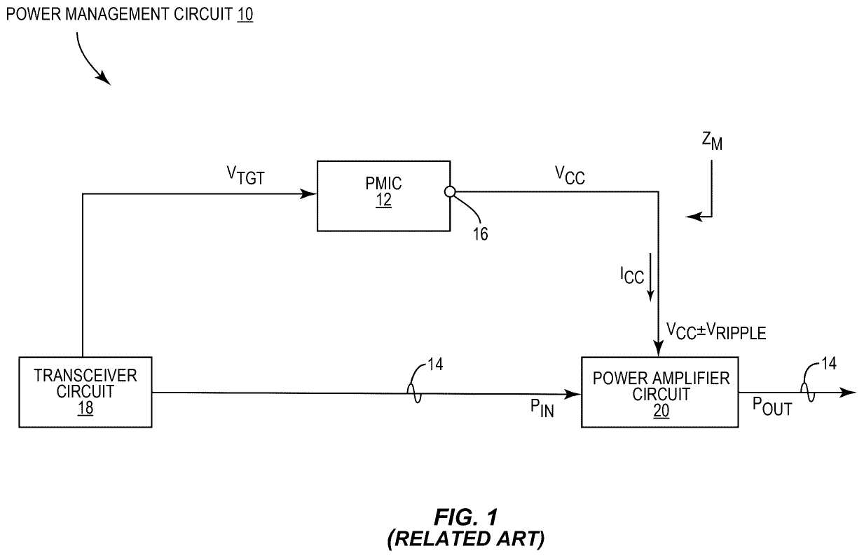

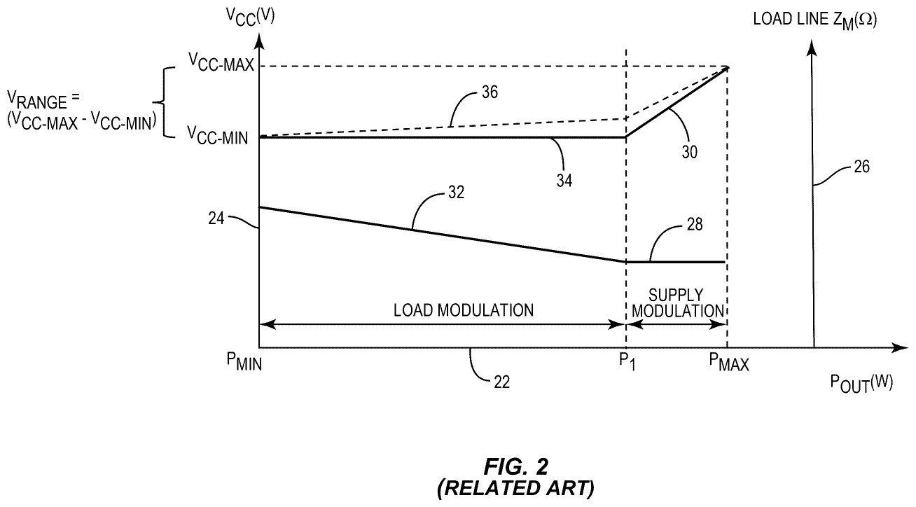

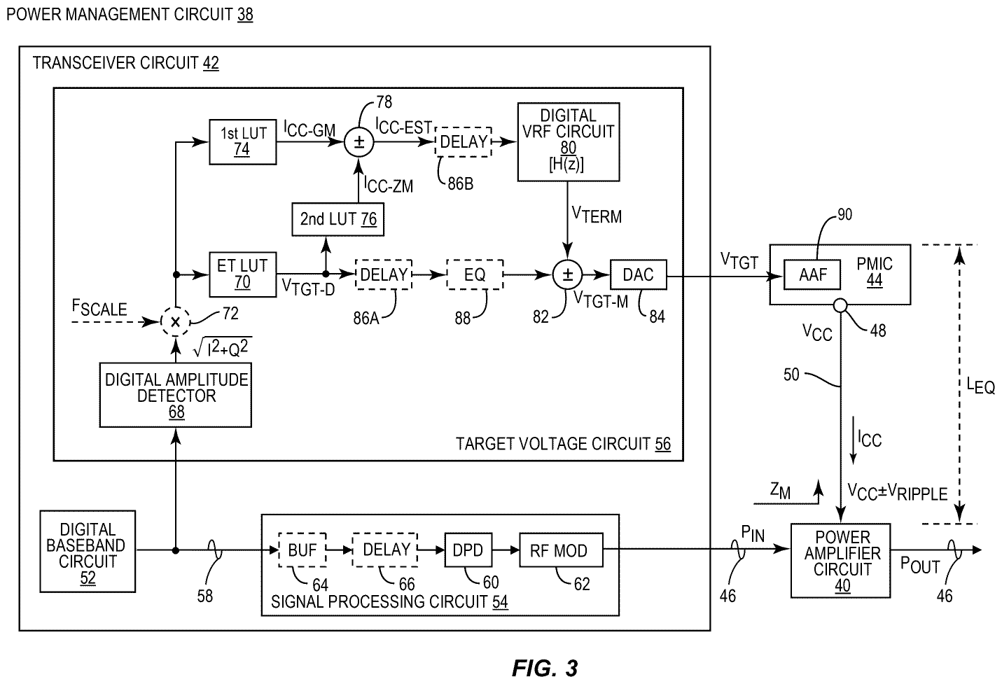

Before discussing the power management circuit of the present disclosure, starting at FIG. 3, a brief discussion of a power management circuit is first provided with reference to FIGS. 1 and 2 to help understand the technical problem to be solved herein.

FIG. 1 is a schematic diagram of an exemplary power management circuit 10 wherein a PMIC 12 can generate a modulated voltage V_{CC} in accordance with a modulated target voltage V_{TGT} for amplifying an RF signal 14 from a time-variant input power P_{IN} to a time-variant output power P_{OUT}. More specifically, the PMIC 12 is configured to generate the modulated voltage V_{CC} at a voltage output 16.

Herein, the power management circuit 10 also includes a transceiver circuit 18 and a power amplifier circuit 20. Specifically, the transceiver circuit 18 is configured to generate the RF signal 14 and the modulated target voltage V_{TGT} that tracks the time-variant input power P_{IN} and/or the time-variant output power P_{OUT} of the RF signal 14. The power amplifier circuit 20, on the other hand, is configured to amplify the RF signal 14 from the time-variant input power P_{IN} to the time-variant output power P_{OUT} based on the modulated voltage V_{CC}. As illustrated in FIG. 1, the power amplifier circuit 20 can be configured to modulate a load line impedance Z_{M} at the voltage output 16 to help improve operating efficiency and linearity of the power management circuit 10.

FIG. 2 is a diagram providing an exemplary illustration as to how the power management circuit 10 of FIG. 1 is operable to generate the modulated voltage V_{CC} in accordance with the time-variant input power P_{IN} and/or the time-variant output power P_{OUT} of the RF signal 14. Common elements between FIGS. 1 and 2 are shown therein with common element numbers and will not be re-described herein.

The plot illustrated herein includes a horizontal axis 22, a first vertical axis 24, and a second vertical axis 26. Specifically, the horizontal axis 22 indicates the output power P_{OUT} of the RF signal 14, the first vertical axis 24 indicates the modulated voltage V_{CC} at the voltage output 16, and the second vertical axis 26 indicates the load line impedance Z_{M} seen at the voltage output 16.

To help the power amplifier circuit 20 to achieve better operating efficiency, the PMIC 12 is configured to generate the modulated voltage V_{CC} in accordance with a power threshold P₁ that is lower than a maximum power threshold P_{MAX} but higher than a minimum power threshold P_{MIN} of the RF signal 14 (P_{MIN}<P₁<P_{MAX}). In a non-limiting example, the power threshold P₁ can be 6 dB below the maximum power threshold P_{MAX} of the RF signal 14 (P₁=P_{MAX}−6 dB).

When the instantaneous power level P_{OUT} of the RF signal 14 is higher than or equal to the power threshold P₁ (P_{OUT}≥P₁), the PMIC 12 is configured to generate the modulated voltage V_{CC} based on a supply modulation. Herein, the 25 supply modulation indicates that the load line impedance Z_{M} (as illustrated by line 28) is kept constant, whereas the modulated voltage V_{CC} (as illustrated by line 30) increases as the time-variant output power P_{OUT} increases toward the maximum power threshold P_{MAX}. In contrast, when the instantaneous power level P_{OUT} of the RF signal 14 is below the power threshold P₁ (P_{OUT}<P₁), the power management circuit 10 may be configured to operate according to one of the following two options when the time-variant output power P_{OUT} increases from the minimum power threshold P_{MIN} toward the power threshold P₁.

In a first option, the power management circuit 10 can generate the modulated voltage V_{CC} based on a load modulation. Herein, the load modulation indicates that the load line impedance Z_{M} (as illustrated by line 32) is reduced while the modulated voltage V_{CC} (as illustrated by line 34) is kept constant at a minimum level V_{CC-MIN}. In a second option, the power management circuit 10 can generate the modulated voltage V_{CC} based on a combination of the load modulation and the supply modulation. Specifically, the modulated voltage V_{CC} (as illustrated by a dotted line 36) may slightly increase from the minimum level V_{CC-MIN} While the load line impedance Z_{M} (as illustrated by line 32) is reduced.

Notably, by applying a combination of load modulation and supply modulation across a larger range of the output power P_{OUT} based on the power threshold P₁, it is possible to raise the minimum level V_{CC-MIN} of the modulated voltage V_{CC}. As a result, a voltage range V_{RANGE} of the modulated voltage V_{CC}, as defined by a maximum level V_{CC-MAX} and the minimum level V_{CC-MIN} of the modulated voltage V_{CC}, can be reduced to help improve operating efficiency of the PMIC 12. For specific embodiments enabling the load modulation and the supply modulation, please refer to U.S. patent application Ser. No. 19/226,326, entitled “POWER MANAGEMENT CIRCUIT OPERABLE WITH A REDUCED VOLTAGE RANGE.”

With reference back to FIG. 1, the modulated voltage V_{CC} can induce a time-variant load current I_{CC} in the power amplifier circuit 20. The time-variant load current I_{CC} can interact with the load line impedance Z_{M} to create a ripple voltage V_{RIPPLE}. As a result, the power amplifier circuit 20 will receive a combination of the ripple voltage V_{RIPPLE} and the modulated voltage V_{CC} (V_{CC}±V_{RIPPLE}) that can cause linearity degradation in the power amplifier circuit 20. In this regard, it is necessary to remove, or at least reduce, the ripple voltage V_{RIPPLE} to help restore linearity at the power amplifier circuit 20.

Given that the ripple voltage V_{RIPPLE} is caused by the interaction of the time-variant load current I_{CC} and the load line impedance Z_{M} and the load line impedance Z_{M} is predicable based on the time-variant output power P_{OUT}, it is thus necessary to determine the time-variant load current I_{CC} induced in the power amplifier circuit 20. Since the power management circuit 10 may operate based on a combination of supply modulation and load modulation, it is understandably difficult to determine the time-variant load current I_{CC} in an analog domain. Thus, the technical problem to be solved herein is to accurately estimate the time-variant load current I_{CC} in a digital domain to thereby remove the ripple voltage V_{RIPPLE} at the power amplifier circuit 20.

In this regard, FIG. 3 is a schematic diagram of an exemplary power management circuit 38 configured according to embodiments of the present disclosure to support digital voltage reconstruction to thereby remove an unwanted ripple voltage V_{RIPPLE} from a modulated voltage V_{CC} at a power amplifier circuit 40. Herein, the power management circuit 38 further includes a transceiver circuit 42 and a PMIC 44. The transceiver circuit 42 is configured to generate an RF signal 46 having a time-variant input power P_{IN} and a modulated target voltage V_{TGT} that is modulated in accordance with the time-variant input power P_{IN}. The PMIC 44 is configured to generate the modulated voltage V_{CC} at a voltage output 48 and provide the modulated voltage V_{CC} to the power amplifier circuit 40 via a conductive trace 50. The modulated voltage V_{CC}, which can be an envelope tracking (ET) voltage, is generated in accordance with the modulated target voltage V_{TGT}. The modulated voltage V_{CC} will induce a time-variant load current I_{CC} in the power amplifier circuit 40. Accordingly, the power amplifier circuit 40 can amplify the RF signal 46 from the time-variant input power P_{IN} to a time-variant output power P_{OUT} based on the modulated voltage V_{CC} and the time-variant load current I_{CC}.

As previously described in FIG. 2, the power management circuit 38 can be configured to perform the supply modulation and the load modulation based on the time-variant input power P_{IN} and/or the time-variant output power P_{OUT}. In this regard, as discussed in FIG. 2, a load line impedance Z_{M} seen at the voltage output 48 will be modulated (a.k.a. load modulation) when the time-variant output power P_{OUT} is below the power threshold P₁ and kept constant (a.k.a. supply modulation) at the voltage output 48 when the time-variant output power P_{OUT} is above the power threshold P₁.

Similar to the power management circuit 10 of FIG. 1, the load line impedance Z_{M} will interact with the time-variant load current I_{CC} to create the unwanted ripple voltage V_{RIPPLE}. Consequently, the power amplifier circuit 40 will receive the modulated voltage V_{CC} that is distorted by the unwanted ripple voltage V_{RIPPLE}. Since the distorted modulated voltage V_{CC} can degrade linearity of the power amplifier circuit 40, it is thus necessary to remove the unwanted ripple voltage V_{RIPPLE} from the modulated voltage V_{CC}.

As mentioned earlier, it is difficult to determine the time-variant load current I_{CC} in the analog domain due to the load modulation and/or the supply modulation. As such, the transceiver circuit 42 is configured to estimate the time-variant load current I_{CC} and determine a voltage reconstruction term V_{TERM} in the digital domain accordingly. Herein, the voltage reconstruction term V_{TERM} is so determined to be substantially equal but opposite to the unwanted ripple voltage V_{RIPPLE} at the power amplifier circuit 40. By adding the voltage reconstruction term V_{TERM} into the modulated target voltage V_{TGT}, the PMIC 44 will be able to generate the modulated voltage V_{CC} to substantially remove the unwanted ripple voltage V_{RIPPLE} to thereby improve linearity of the power amplifier circuit 40.

The transceiver circuit 42 includes a digital baseband circuit 52, a signal processing circuit 54, and a target voltage circuit 56. The digital baseband circuit 52 is configured to generate a digital signal 58 and the signal processing circuit 54 is configured to convert the digital signal 58 into the RF signal 46. Specifically, the signal processing circuit 54 includes a digital pre-distortion (DPD) circuit 60 and an RF modulation circuit 62. The DPD circuit 60 is configured to digitally pre-distort the digital signal 58 to help improve linearity of the digital signal 58 and the RF modulation circuit 62 is configured to convert the pre-distorted digital signal 58 into the RF signal 46. The signal processing circuit 54 may further include a data buffer 64 and a signal delay circuit 66, which can provide proper alignment between the RF signal 46 and the modulated voltage V_{CC} at the power amplifier circuit 40.

The target voltage circuit 56 includes a digital amplitude detector 68 and an ET lookup table (LUT) 70. Herein, the digital signal 58 is so generated to include an in-phase (I) component and a quadrature (Q) component. Accordingly, the digital amplitude detector 68 is configured to detect a time-variant amplitude \sqrt{I²+Q²} of the digital signal 58. In an embodiment, the target voltage circuit 56 may also include a scaler 72 that scales the time-variant amplitude \sqrt{I²+Q²} of the digital signal 58 based on a scaling factor F_{SCALE}.

In an embodiment, the ET LUT 70 is preconfigured to correlate the time-variant amplitude \sqrt{I²+Q²} of the digital signal 58 with a time-variant voltage amplitude. Accordingly, the ET LUT 70 can generate a digital target voltage V_{TGT-D} having the time-variant voltage amplitude that tracks the time-variant amplitude \sqrt{I²+Q²} of the digital signal 58.

According to an embodiment of the present disclosure, the target voltage circuit 56 is configured to estimate the time-variant load current I_{CC} based on a pair of preconfigured LUTs. More specifically, the target voltage circuit 56 includes a first LUT 74 and a second LUT 76. The first LUT 74 is configured to estimate a gain-related load current I_{CC-GM} as a function of the time-variant amplitude \sqrt{I²+Q²} of the digital signal 58. The second LUT 76 is configured to estimate an impedance-related load current I_{CC-ZM} as a function of the time-variant voltage amplitude of the digital target voltage V_{TGT-D}. In an embodiment, the first LUT 74 can be preconfigured and/or calibrated to map the time-variant amplitude \sqrt{I²+Q²} of the digital signal 58 with various levels of the gain-related load current I_{CC-GM}. Likewise, the second LUT 76 can also be preconfigured and/or calibrated to map the time-variant voltage amplitude of the digital target voltage V_{TGT-D} with various levels of the impedance-related load current I_{CC-ZM}.

The target voltage circuit 56 also includes a current combiner 78. Herein, the current combiner 78 is configured to combine the estimated gain-related load current I_{CC-GM} and the estimated impedance-related load current I_{CC-ZM} to thereby generate an estimated time-variant load current I_{CC-EST}.

The target voltage circuit 56 further includes a digital voltage reconstruction filter (VRF) circuit 80. The digital VRF circuit 80 is configured to apply a voltage reconstruction filter H(z) to the estimated time-variant load current I_{CC-EST} to thereby determine the voltage reconstruction term V_{TERM}.

In a first embodiment, the voltage reconstruction filter H(z) can be determined based on a z-transformation equation (Eq. 1) below.

$$H ( z ) = 1 + {L}_{EQ} / {R}_{M} * ( 1 - {z}^{- 1} ) * {f}_{S} \qquad ( Eq . 1 )$$

Herein, L_{EQ} represents an equivalent inductance between the PMIC 44 and the power amplifier circuit 40. In a non-limiting example, the equivalent inductance L_{EQ} includes an inductive impedance of the PMIC 44, an inductance of the conductive trace 50, and a capacitive impedance of the power amplifier circuit 40. In addition, R_{M} represents a real part of the load line impedance Z_{M}, z⁻¹ represents a time delay of z-transformation, and f_{S} represents a sampling frequency of the digital VRF circuit 80.

In a second embodiment, the voltage reconstruction filter H(z) can also be determined based on a z-transformation equation (Eq. 2) below.

$$H ( z ) = 1 + {L}_{EQ} / {R}_{M} * ( 1 - {z}^{- 1} ) / ( 1 + {z}^{- 1} ) * 2 * {f}_{S} \qquad ( Eq . 2 )$$

The target voltage circuit 56 further includes a voltage combiner 82 and a digital-to-analog converter (DAC) 84. The voltage combiner 82 is configured to add the voltage reconstruction term V_{TERM} to the digital target voltage V_{TGT-D} to thereby generate a modified digital target voltage V_{TGT-M}. The DAC 84 subsequently converts the modified digital target voltage V_{TGT-M} into the modulated target voltage V_{TGT}.

The target voltage circuit 56 may further include one or more delay circuits 86A, 86B. In a non-limiting example, the delay circuits 86A, 86B are configured to align the digital target voltage V_{TGT-D} and the voltage reconstruction term V_{TERM} at the voltage combiner 82. In an embodiment, the digital target voltage V_{TGT-D} may be equalized by an equalizer 88 before being combined with the voltage reconstruction term V_{TERM} at the voltage combiner 82.

In an embodiment, the PMIC 44 is configured to include an anti-aliasing filter (AAF) 90, which is configured to remove high-frequency content from the modulated target voltage V_{TGT} before generating the modulated voltage V_{CC} based on the modulated target voltage V_{TGT}. As the transceiver circuit 42 is configured to estimate the time-variant load current I_{CC} and determine the voltage reconstruction term V_{TERM} in the digital domain, the PMIC 44 can thus be implemented on a smaller footprint.

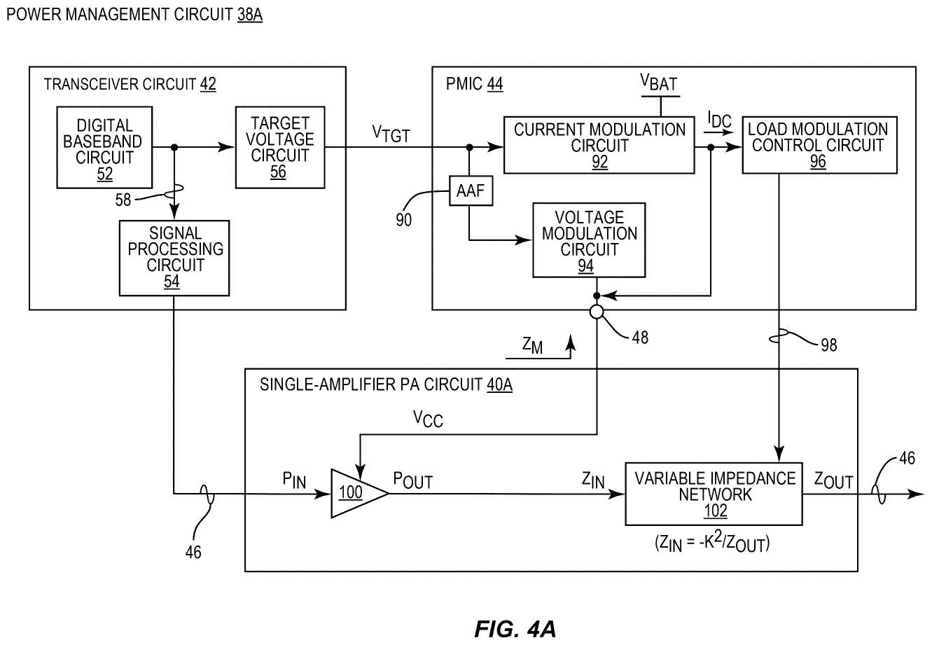

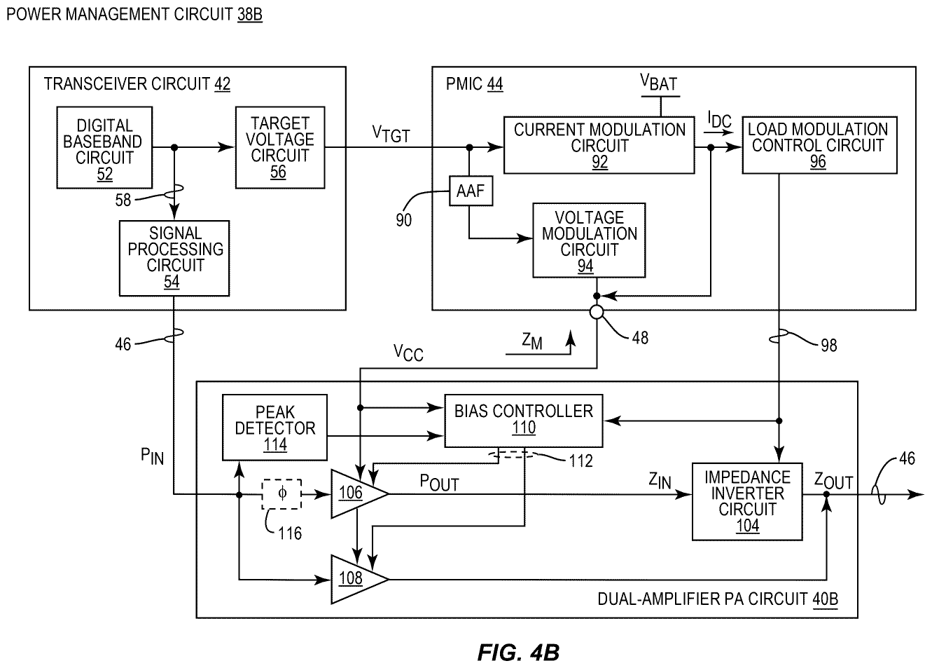

In one embodiment, the power amplifier circuit 40 can be a single-amplifier power amplifier circuit, as illustrated in FIG. 4A. In another embodiment, the power amplifier circuit 40 can also be a dual-amplifier power amplifier circuit, as illustrated in FIG. 4B. Common elements between FIGS. 3, 4A, and 4B are shown therein with common element numbers and will not be re-described herein.

FIG. 4A is a schematic diagram of an exemplary power management circuit 38A wherein a single-amplifier power amplifier circuit 40A is configured to perform the load modulation as described in FIG. 2. Herein, the PMIC 44 includes a current modulation circuit 92, a voltage modulation circuit 94, and a load modulation control circuit 96. The current modulation circuit 92 is configured to generate a low-frequency current I_{DC} as a function of a battery voltage VBAT. The current modulation circuit 92 is also configured to provide the low-frequency current I_{DC} to the load modulation control circuit 96 and the voltage output 48. The voltage modulation circuit 94 is configured to generate the modulated voltage V_{CC} based on the modulated target voltage V_{TGT}. The load modulation control circuit 96 is configured to generate a load modulation signal 98 to thereby cause the single-amplifier power amplifier circuit 40A to dynamically modulate the load line impedance Z_{M} when the instantaneous power level P_{OUT} of the RF signal 46 is below the power threshold P₁.

As the name suggests, the single-amplifier power amplifier circuit 40A can include an amplifier 100 coupled in series to a variable impedance network 102. The amplifier 100 is configured to amplify the RF signal 46 from the time-variant input power P_{IN} to the time-variant output power P_{OUT} based on the modulated voltage V_{CC}. The variable impedance network 102, which can be an acoustic-based impedance network, is configured to modulate the load line impedance Z_{M} in response to receiving the load modulation signal 98.

In a non-limiting example, the variable impedance network 102 can be a variable impedance inverter network configured to influence the load line impedance Z_{M} in accordance with the equation (Eq. 3) below.

$${Z}_{IN} = - {K}^{2} / {Z}_{OUT} \qquad ( Eq . 3 )$$

In the equation (Eq. 3), Z_{IN} represents an input impedance seen by the variable impedance network 102, K represents a tunable gain factor of the variable impedance network 102, and Z_{OUT} represents an output impedance seen by the variable impedance network 102 (e.g., impedance of a downstream circuit). In an embodiment, the tunable gain factor K can be electrically tuned in accordance with the output impedance Z_{OUT} to thereby change the input impedance Z_{IN}. Notably, the load line impedance Z_{M} can be a function of the input impedance Z_{IN}. Accordingly, by electrically tuning the input impedance Z_{IN}, it is thus possible to influence the load line impedance Z_{M}. For a more detailed description of various embodiments of the single-amplifier power amplifier circuit 40A, please refer to U.S. Provisional Patent Application No. 63/684,919, entitled “DYNAMIC IMPEDANCE MODULATION IN A POWER MANAGEMENT CIRCUIT.”

FIG. 4B is a schematic diagram of an exemplary power management circuit 38B wherein a dual-amplifier power amplifier circuit 40B is configured to perform the load modulation as described in FIG. 2. Herein, the dual-amplifier power amplifier circuit 40B includes an impedance inverter circuit 104, a first amplifier 106, a second amplifier 108, and a bias controller 110. In an embodiment, the impedance inverter circuit 104 is coupled to the load modulation control circuit 96 to receive the load modulation signal 98. The first amplifier 106 and the second amplifier 108 are each coupled to the voltage modulation circuit 94 and the impedance inverter circuit 104.

Notably, the first amplifier 106 is active all the time when the instantaneous output power P_{OUT} of the RF signal 46 is below the power threshold P₁, whereas the second amplifier 108 is only activated as needed when the instantaneous output power P_{OUT} of the RF signal 46 is below the power threshold P₁. In this regard, the bias controller 110 can be configured to always bias the first amplifier 106 in response to receiving the load modulation signal 98 that indicates the load modulation (corresponding to the line 34 in FIG. 2), and only bias the second amplifier 108 in response to receiving the load modulation signal 98 that indicates the combination of load modulation and supply modulation (corresponding to the dotted line 36 in FIG. 2). Notably, by activating the second amplifier 108, it is possible to change the slope of the load modulation between the line 34 and the dotted line 36. In a non-limiting example, the bias controller 110 may bias the first amplifier 106 and the second amplifier 108 via a bias signal 112.

In an embodiment, the dual-amplifier power amplifier circuit 40B can be configured to further include a peak detector 114. Accordingly, the peak detector 114 can help the bias controller 110 to control the second amplifier 108 based on the time-variant input power P_{IN} of the RF signal 46. In another embodiment, the dual-amplifier power amplifier circuit 40B can further include a phase adjuster 116, which is coupled to the first amplifier 106 to perform phase adjustment of the RF signal 46. For a more detailed description of various embodiments of the dual-amplifier power amplifier circuit 40B, please refer to PCT Patent Application Number PCT/US2025/033449, entitled “CONTROLLING A DUAL-AMPLIFIER POWER AMPLIFIER CIRCUIT IN A POWER MANAGEMENT CIRCUIT.”

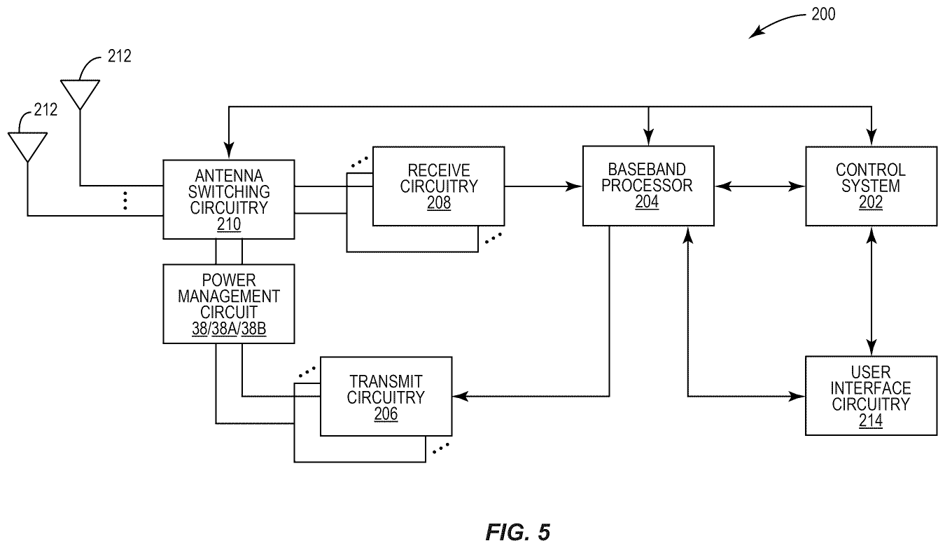

The power management circuit 38 of FIG. 3, the power management circuit 38A of FIG. 4A, and the power management circuit 38B of FIG. 4B can be provided in a communication device to support the embodiments described above. In this regard, FIG. 5 is a schematic diagram of an exemplary communication device 200 wherein the power management circuit 10 of FIG. 3, the power management circuit 38A of FIG. 4A, and the power management circuit 38B of FIG. 4B can be provided.

Herein, the communication device 200 can be any type of communication devices, such as mobile terminals, smart watches, tablets, computers, navigation devices, access points, base stations (e.g., eNB, gNB, etc.), and like wireless communication devices that support wireless communications, such as cellular, wireless local area network (WLAN), Ultra-wideband (UWB), Bluetooth, and near-field communications. The communication device 200 will generally include a control system 202, a baseband processor 204, transmit circuitry 206, receive circuitry 208, antenna switching circuitry 210, multiple antennas 212, and user interface circuitry 214. In a non-limiting example, the control system 202 can be a field-programmable gate array (FPGA), as an example. In this regard, the control system 202 can include at least a microprocessor, an embedded memory circuit, and a communication bus interface. The receive circuitry 208 receives radio frequency signals via the antennas 212 and through the antenna switching circuitry 210 from one or more base stations. A low-noise amplifier and a filter cooperate to amplify and remove broadband interference from the received signal for processing. Downconversion and digitization circuitry (not shown) will then downconvert the filtered, received signal to an intermediate or baseband frequency signal, which is then digitized into one or more digital streams using analog-to-digital converters (ADCs).

The baseband processor 204 processes the digitized received signal to extract the information or data bits conveyed in the received signal. This processing typically comprises demodulation, decoding, and error correction operations, as will be discussed in greater detail below. The baseband processor 204 is generally implemented in one or more digital signal processors (DSPs) and application-specific integrated circuits (ASICs).

For transmission, the baseband processor 204 receives digitized data, which may represent voice, data, or control information, from the control system 202, which it encodes for transmission. The encoded data is output to the transmit circuitry 206, where a digital-to-analog converter (DAC) converts the digitally encoded data into an analog signal and a modulator modulates the analog signal onto a carrier signal that is at a desired transmit frequency or frequencies. A power amplifier will amplify the modulated carrier signal to a level appropriate for transmission and deliver the modulated carrier signal to the antennas 212 through the antenna switching circuitry 210. The multiple antennas 212 and the replicated transmit 206 and receive circuitry 208 may provide spatial diversity. Modulation and processing details will be understood by those skilled in the art.

In an embodiment, the transmit circuitry 206 and the receive circuitry 208 can function as a transceiver circuit. Accordingly, the power management circuit 38, the power management circuit 38A, and the power management circuit 38B can be provided between the transmit circuitry 206 and the antenna switching circuitry 210.

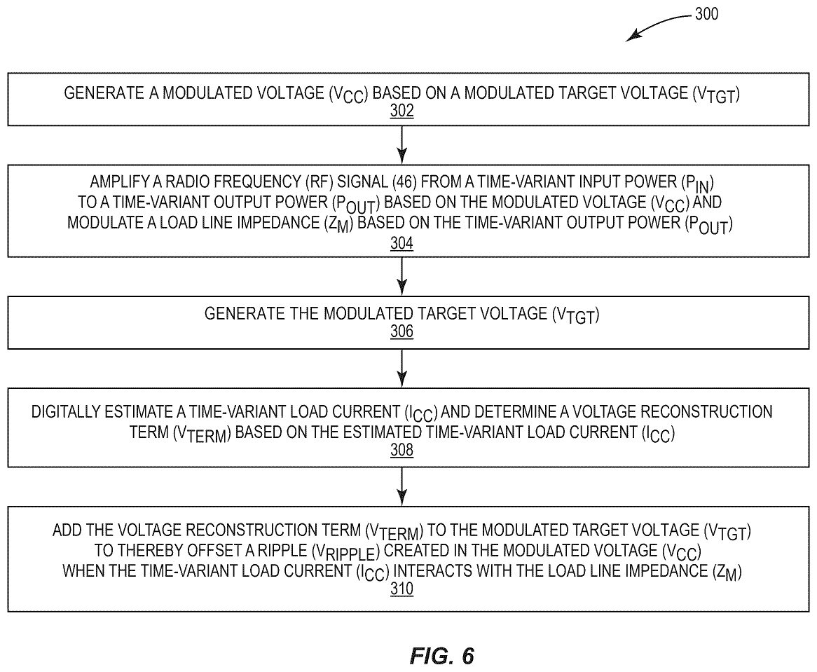

In an embodiment, the power management circuit 38 of FIG. 3 can be configured to support digital voltage reconstruction in accordance with a process. In this regard, FIG. 6 is a flowchart of an exemplary process 300 for supporting digital voltage reconstruction in the power management circuit 38 of FIG. 3.

Herein, the process 300 includes generating the modulated voltage V_{CC} based on the modulated target voltage V_{TGT} (step 302). The process 300 also includes amplifying the RF signal 46 from the time-variant input power P_{IN} to the time-variant output power P_{OUT} based on the modulated voltage V_{CC} and modulating the load line impedance Z_{M} based on the time-variant output power P_{OUT} (step 304). The process 300 also includes generating the modulated target voltage V_{TGT} (step 306). The process 300 also includes digitally estimating the time-variant load current I_{CC} and determining the voltage reconstruction term V_{TERM} based on the estimated time-variant load current I_{CC} (step 308). The process 300 further includes adding the voltage reconstruction term V_{TERM} to the modulated target voltage V_{TGT} to thereby offset the ripple V_{RIPPLE} created in the modulated voltage V_{CC} when the time-variant load current I_{CC} interacts with the load line impedance Z_{M} (step 310).

Those skilled in the art will recognize improvements and modifications to the preferred embodiments of the present disclosure. All such improvements and modifications are considered within the scope of the concepts disclosed herein and the claims that follow.

What is claimed is:

1. A power management circuit comprising:
a power management integrated circuit (PMIC) configured to generate a modulated voltage at a voltage output based on a modulated target voltage;
a power amplifier circuit configured to amplify a radio frequency (RF) signal from a time-variant input power to a time-variant output power based on the modulated voltage and modulate a load line impedance at the voltage output based on the time-variant output power; and
a transceiver circuit comprising a target voltage circuit configured to:
generate the modulated target voltage and provide the modulated target voltage to the PMIC;
digitally estimate a time-variant load current in the power amplifier circuit and determine a voltage reconstruction term based on the estimated time-variant load current; and
add the voltage reconstruction term to the modulated target voltage to thereby offset a ripple created in the modulated voltage when the time-variant load current interacts with the load line impedance.

2. The power management circuit of claim 1, wherein the transceiver circuit further comprises:
a digital baseband circuit configured to generate a digital signal;
a signal processing circuit configured to generate the RF signal from the digital signal;
a digital amplitude detector configured to detect a time-variant amplitude of the digital signal; and
an envelope tracking (ET) lookup table (LUT) configured to generate a digital target voltage having a time-variant voltage amplitude tracking the time-variant amplitude of the digital signal.

3. The power management circuit of claim 2, wherein the target voltage circuit comprises:
a first LUT configured to estimate a gain-related load current as a function of the time-variant amplitude of the digital signal;
a second LUT configured to estimate an impedance-related load current as a function of the time-variant voltage amplitude;
a current combiner configured to combine the estimated gain-related load current and the estimated impedance-related load current to thereby generate the estimated time-variant load current; and
a digital voltage reconstruction filter (VRF) circuit configured to apply a voltage reconstruction filter to the estimated time-variant load current to thereby determine the voltage reconstruction term.

4. The power management circuit of claim 3, wherein the voltage reconstruction filter can be expressed as: H(z)=1+L_{EQ}/R_{M}*(1−z⁻¹)*f_{S}, wherein:
H(z) represents a z-transformation of the voltage reconstruction filter;
L_{EQ} represents an equivalent inductance between the PMIC and the power amplifier circuit;
R_{M} represents a real part of the load line impedance;
z⁻¹ represents a time delay of the z-transformation; and
f_{S} represents a sampling frequency of the digital VRF circuit.

5. The power management circuit of claim 3, wherein the voltage reconstruction filter can be expressed as: H(z)=1+L_{EQ}/R_{M}*(1−z⁻¹)/(1+z⁻¹)*2f_{S}, wherein:
H(z) represents a z-transformation of the voltage reconstruction filter;
L_{EQ} represents an equivalent inductance between the PMIC and the power amplifier circuit;
R_{M} represents a real part of the load line impedance;
z⁻¹ represents a time delay of the z-transformation; and
f_{S} represents a sampling frequency of the digital VRF circuit.

6. The power management circuit of claim 3, wherein the target voltage circuit further comprises:
a voltage combiner configured to add the voltage reconstruction term to the digital target voltage to thereby generate a modified digital target voltage; and
a digital-to-analog converter (DAC) configured to convert the modified digital target voltage into the modulated target voltage.

7. The power management circuit of claim 6, wherein the target voltage circuit further comprises one or more delay circuits configured to align the digital target voltage and the voltage reconstruction term at the voltage combiner.

8. The power management circuit of claim 1, wherein the PMIC comprises an anti-aliasing filter (AAF) configured to remove high-frequency content from the modulated target voltage before generating the modulated voltage based on the modulated target voltage.

9. A wireless device comprising a power management circuit, the power management circuit comprises:
a power management integrated circuit (PMIC) configured to generate a modulated voltage at a voltage output based on a modulated target voltage;
a power amplifier circuit configured to amplify a radio frequency (RF) signal from a time-variant input power to a time-variant output power based on the modulated voltage and modulate a load line impedance at the voltage output based on the time-variant output power; and
a transceiver circuit comprising a target voltage circuit configured to:
generate the modulated target voltage and provide the modulated target voltage to the PMIC;
digitally estimate a time-variant load current in the power amplifier circuit and determine a voltage reconstruction term based on the estimated time-variant load current; and
add the voltage reconstruction term to the modulated target voltage to thereby offset a ripple created in the modulated voltage when the time-variant load current interacts with the load line impedance.

10. The wireless device of claim 9, wherein the transceiver circuit further comprises:
a digital baseband circuit configured to generate a digital signal;
a signal processing circuit configured to generate the RF signal from the digital signal;
a digital amplitude detector configured to detect a time-variant amplitude of the digital signal; and
an envelope tracking (ET) lookup table (LUT) configured to generate a digital target voltage having a time-variant voltage amplitude tracking the time-variant amplitude of the digital signal.

11. The wireless device of claim 10, wherein the target voltage circuit comprises:
a first LUT configured to estimate a gain-related load current as a function of the time-variant amplitude of the digital signal;
a second LUT configured to estimate an impedance-related load current as a function of the time-variant voltage amplitude;
a current combiner configured to combine the estimated gain-related load current and the estimated impedance-related load current to thereby generate the estimated time-variant load current; and
a digital voltage reconstruction filter (VRF) circuit configured to apply a voltage reconstruction filter to the estimated time-variant load current to thereby determine the voltage reconstruction term.

12. The wireless device of claim 11, wherein the voltage reconstruction filter can be expressed as: H(z)=1+L_{EQ}/R_{M}*(1−z⁻¹)*f_{S}, wherein:
H(z) represents a z-transformation of the voltage reconstruction filter;
L_{EQ} represents an equivalent inductance between the PMIC and the power amplifier circuit;
R_{M} represents a real part of the load line impedance;
z⁻¹ represents a time delay of the z-transformation; and
f_{S} represents a sampling frequency of the digital VRF circuit.

13. The wireless device of claim 11, wherein the voltage reconstruction filter can be expressed as: H(z)=1+L_{EQ}/R_{M}*(1−z⁻¹)/(1+z⁻¹)*2f_{S}, wherein:
H(z) represents a z-transformation of the voltage reconstruction filter;
L_{EQ} represents an equivalent inductance between the PMIC and the power amplifier circuit;
R_{M} represents a real part of the load line impedance;
z⁻¹ represents a time delay of the z-transformation; and
f_{S} represents a sampling frequency of the digital VRF circuit.

14. The wireless device of claim 11, wherein the target voltage circuit further comprises:
a voltage combiner configured to add the voltage reconstruction term to the digital target voltage to thereby generate a modified digital target voltage; and
a digital-to-analog converter (DAC) configured to convert the modified digital target voltage into the modulated target voltage.

15. The wireless device of claim 14, wherein the target voltage circuit further comprises one or more delay circuits configured to align the digital target voltage and the voltage reconstruction term at the voltage combiner.

16. The wireless device of claim 9, wherein the PMIC comprises an anti-aliasing filter (AAF) configured to remove high-frequency content from the modulated target voltage before generating the modulated voltage based on the modulated target voltage.

17. A method for supporting digital voltage reconstruction in a power management circuit comprising:
generating a modulated voltage based on a modulated target voltage;
amplifying a radio frequency (RF) signal from a time-variant input power to a time-variant output power based on the modulated voltage and modulating a load line impedance based on the time-variant output power;
generating the modulated target voltage;
digitally estimating a time-variant load current and determining a voltage reconstruction term based on the estimated time-variant load current; and
adding the voltage reconstruction term to the modulated target voltage to thereby offset a ripple created in the modulated voltage when the time-variant load current interacts with the load line impedance.

18. The method of claim 17, further comprising:
generating a digital signal and generating the RF signal from the digital signal;
detecting a time-variant amplitude of the digital signal; and
generating a digital target voltage having a time-variant voltage amplitude tracking the time-variant amplitude of the digital signal.

19. The method of claim 18, further comprising:
estimating a gain-related load current as a function of the time-variant amplitude of the digital signal;
estimating an impedance-related load current as a function of the time-variant voltage amplitude;
combining the estimated gain-related load current and the estimated impedance-related load current to thereby generate the estimated time-variant load current;
applying a voltage reconstruction filter to the estimated time-variant load current to thereby determine the voltage reconstruction term;
adding the voltage reconstruction term to the digital target voltage to thereby generate a modified digital target voltage; and
converting the modified digital target voltage into the modulated target voltage.

20. The method of claim 17, further comprising removing high-frequency content from the modulated target voltage before generating the modulated voltage based on the modulated target voltage.
